(19) United States
(12) Patent Application Publication
(10) Pub. No.: US 2013/0158903 A1
(43) Pub. Date: Jun. 20, 2013

(54) Method and System for Detecting Transients in Power Grids

(71) Applicant: Mitsubishi Electric Research Corporation, Inc., Cambridge, MA (US)

(72) Inventors: Zafer Sahinoglu, Cambridge, MA (US); Jianlin Guo, Newton, MA (US); Xiufeng Song, Willington, CT (US)

(73) Assignee: Mitsubishi Electric Research Corporation, Inc., Cambridge, MA (US)

(21) Appl. No.: 13/677,752

(22) Filed: Nov. 15, 2012

Related U.S. Application Data
(63) Continuation-in-part of application No. 13/329,720, filed on Dec. 19, 2011.

(51) Int. Cl. G01R 31/02; G06F 17/18

(52) U.S. Cl. CPC G01R 31/02; G06F 17/18
USPC 702/58

(57) ABSTRACT

Conditions in a power grid are detected by sampling a voltage in the grid. A normal condition hypothesis is modeled as a sinusoid, and a transient condition hypothesis is modeled as a sum of damped sinusoids. The samples are used to construct probability density function. A likelihood ratio based on the pdf and the hypotheses is compared to a threshold to determine whether the condition is normal or transient.

### RELATED APPLICATION

This is a continuation in part of U.S. patent application Ser. No. 13/329,720 “Method and System for Detecting Unbalance in Power Grids” filed by Sahinoglu et al. on Dec. 19, 2011, and incorporated herein by reference. The related application also discloses detecting a condition in a power grid.

### FIELD OF THE INVENTION

This invention relates generally to detecting conditions in a power grid, and in particular to detecting transients.

### BACKGROUND OF THE INVENTION

Power Grid Transients

In a power grid, a transient is a short time disturbance in the voltage or current. Typically the transient is due to an unexpected load or generator mismatch. Some transients are due to external natural phenomena, such as lightning. However, the majority of transients are internally generated by, e.g., load switching, breaker switching, fuse disconnection, short-circuit, or islanding. During transients, a secondary or distributed generator continues to power a local portion of the grid, even though power from the primary power source is no longer present.

The amount of voltage or current change during the transient is case dependent. For example, a short circuit can cause a large current increase. The cumulative effect of transients can damage semiconductors that are extensively integrated in modern power grids. Unintentional transients can be a danger to utility workers, consumers and equipment. As a consequence, transients must be detected.

Spectrum analysis of transients is known. Conventional approaches include Fourier and wavelet transforms base analysis. Power grids can be described by differential equations. Another approach uses estimation of signal parameters via rotational invariance techniques (ESPRIT).

FIG. 1 shows a prior art transient detection. A rectifier 110 is connected to a secondary power source 100, e.g., a distributed power source, such as a solar panel, a wind turbine, or a backup generator, and an inverter 120, e.g., a 1- or 3-phase inverter. The inverter is also connected to a primary power source 140 via a circuit breaker 130. The primary power source can be one or more large scale conventional generators, or other power grids. An output of a predictive controller 190 is connected to the inverter. Inputs to the controller include samples of a measured voltage (V) 180, and a moving average of the frequency (F) 170. The inverter and primary source can also be connected to a load 150.

U.S. Pat. No. 8,195,414 detects transients condition by altering a phase error response within a phase locked loop, and determining whether the transient is based on an altered phase error response.

U.S. Pat. No. 7,376,491 detects transients by monitoring a detectable signal different from power line voltage at a generating station, superimposing the detectable signal onto the power line voltage at a grid point outside the generating station.

U.S. 20110276192 detects transients using a solar power inverter. The inverter calculates a degree of correlation between the electrical power grid AC frequency and the frequency of the electrically proximate AC. If the degree of correlation dips below a predefined value or exhibits certain patterns or behaviors, this is indicative of a loss of main power.

Brown Out

The related application Ser. No. 13/329,720 describes detecting an unbalance condition in a power grid using probability density functions. The unbalance condition could be due to a substantial decrease in voltage as during a brown out. This condition can be relatively long term, e.g., minutes to hours, when compared with transients on the order of milliseconds.

### SUMMARY OF THE INVENTION

The embodiments of the invention provide a method and system for detecting transients in a power grid. The detection uses a binary hypothesis test, and a general likelihood ratio test (GLRT). The GLRT involves a maximum likelihood estimation (MLE) of unknown model parameters.

Because this is a computational complex problem, the embodiments obtain unknown signal parameters via an estimation of signal parameters via rotational invariance techniques (ESPRIT) to replace the MLE for parameter estimation.

The method does not require any prior knowledge of the fundamental frequency, initial phase, or amplitude of the voltage. Therefore, performance of the method is preserved under non-ideal situations, such as frequency deviation from the nominal frequency of the power grid.

Embodiments of the invention construct a probability distribution function (pdf) of measured samples of a voltage signal in the grid to detect transient samples. The normal pdf and islanded pdf can be used because they have different means and covariances.

A likelihood ratio test determines whether the signal samples correspond to a normal condition hypothesis (H₀), or the transient condition hypothesis (H₁).

In one embodiment, the transient detection is formulated as a parameter test, which is solved using a generalized likelihood ratio test (GLRT). As used by this embodiment, the GLRT is a statistical test to compare the fit of two models, one of which is a model for the normal condition, and the other a model for the transient condition. The test is based on the likelihood ratio of the models.

For example, if the GLRT ratio is not equal to one, then the transient is detected. In one variation of this embodiment, the transient is detected if a difference between one and the ratio is greater than a threshold.

### BRIEF DESCRIPTION OF THE DRAWINGS

FIG. 1 is a block diagram of a prior art transient detector;

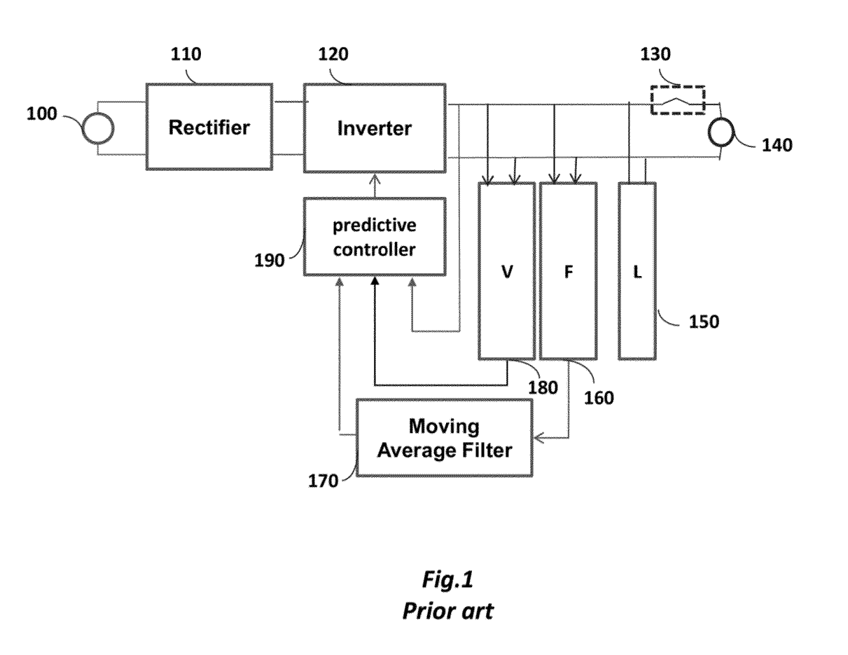

FIG. 2 is a block diagram of a method and system for detecting transients in a power grid according an embodiment of an invention;

FIG. 3 is a block diagram of the stochastic transient detector and process according to embodiments of the invention;

FIG. 4 is a block diagram of parameter estimation under transient condition according to one embodiment of the invention; and

FIG. 5 are signal waveforms used by embodiments of the intervention.

### DETAILED DESCRIPTION OF THE EMBODIMENTS

System Method Overview

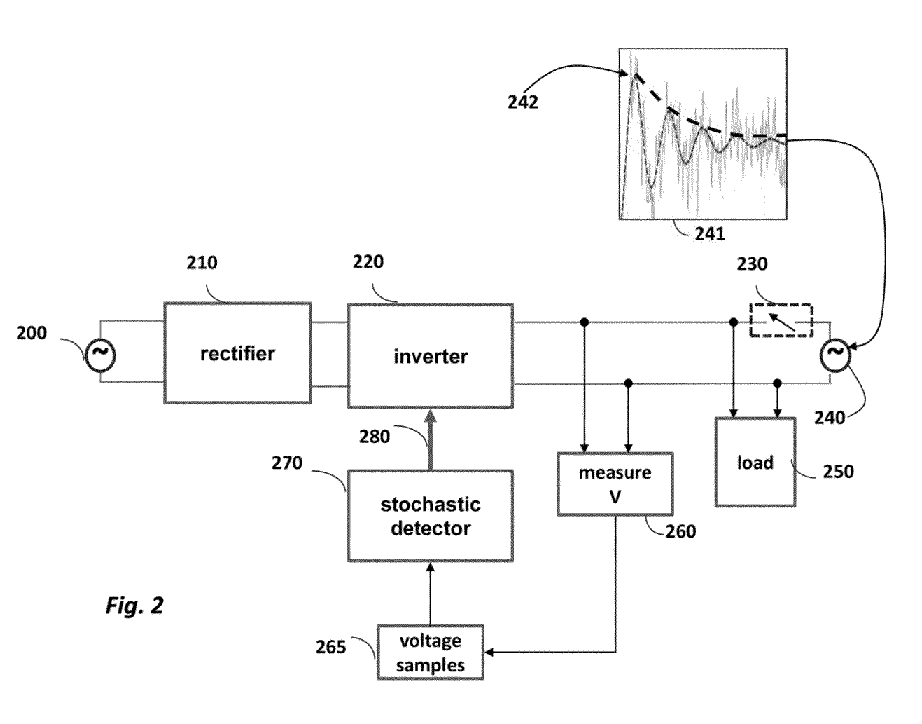

FIG. 2 shows a method and system for detecting transients in a local portion of a 1- or 3-phase power grid. A rectifier 210 is connected to a secondary power source 200, e.g., a distributed power source such as a solar panel, a wind turbine, or a backup generator, and an inverter 220. The inverter is also connected to a primary power source 240 via a circuit breaker 230. An output of a stochastic detector 270 is connected to the inverter. An input to the detector includes samples of measured voltages (V) 260, described in greater detail below. The samples can be normal or transients samples. The inverter and source 240 can also be connected to a load 250. Output of the detector is a decision 280, whether a transient is detected, or not. The decision can be used to “connect” the power sources in the grid according to the detected condition. As used herein, connect can mean either connect or disconnect any of the power sources in the grid.

Because the time to respond to this condition is relatively short, the method measures 260 samples 265 of the voltage signal in the grid to obtain samples. The stochastic detector analyzes the samples in real-time to detect transient samples during a transient condition, or a normal samples during a normal condition by fitting the samples to probability density functions as described in greater detail below.

The waveform 241 shows a typical onset of transient, where an average amplitude 242 the output voltage of the primary source 240 decreases rapidly in a matter of milliseconds. The example waveform is for one second. Therefore, we continuously sample at about 8 kHz, and use a sliding window to test the current short term grid conditions.

This condition is quite different than that described in the related application. Instead of a long term decrease in voltage, with possible recovery at anytime, here we have, e.g., a sudden decrease in voltage amplitude to zero. It is important to quickly recognize this condition so that the secondary power source can be connected. This is particular important in applications where the loss of power to electric equipment can be life-threatening. Alternatively, the appropriate response may be to disconnect the primary power source.

Voltage Signal Representation

Normal

During a normal grid condition, the voltage signal can be represented as a sinusoid

y(n)=a₀e^{jω}^{₀}ⁿ+v(n), (1)

where n is an integer sampling index, a₀ is a complex amplitude of the fundamental frequency component, i.e., a product of the amplitude and the initial phase, v(n) represents the noise, and ω₀ is a normalized fundamental frequency. The analogy fundamental frequency \tilde{ω}₀ can be obtained by

$${\tilde{ω}}_{0} = \frac{{ω}_{0}}{Δ t} ,$$

where Δt denotes the sampling interval. Note that as signal models for voltage and current are mathematically identical.

Transient

If the gird suffers from an abnormal condition disturbances, such as load switching and transients, then voltage or current signal is subject to a short term transient. Generally, the transient can be modeled as a sum of damped sinusoids.

$$y ( n ) = {\sum }_{i = 1}^{M} {a}_{i} {e}^{- {γ}_{i} n} {e}^{{jω}_{i} n} + v ( n ) , \qquad ( 2 )$$

where γᵢ>0 is a normalized damping coefficient for the i^{th} components of a particular sinusoid, the number of sinusoids is M>0.

Binary Hypothesis Test

Based on the above, a normal condition hypothesis H₀ is modeled as a sinusoid, and a transient condition hypothesis H₁ is modeled as a sum of damped sinusoids.

Hence, the normal condition hypothesis is

H₀:y(n)=a₀e^{jω}^{₀}ⁿ+v(n), and

the transient condition hypothesis is

$${H}_{1} : y ( n ) = {\sum }_{i = 1}^{M} {a}_{i} {e}^{- {γ}_{i} n} {e}^{{jω}_{i} n} + v ( n ) .$$

For N samples, we define y=[y(0),y(1), . . . , y(N−1)]^{T} and v=[v(0),v(1), . . . , v(N−1)]^{T}. Hence, the binary hypothesis test can be compactly expressed in matrix format as

H₀:y=a₀e+v, and

H₁:y=C(N,M)a+v, (3)

a=[a₁,a₂, . . . , a_{M}]^{T}e=[1,e^{jw}^{₀}, . . . , e^{jw}^{₀}^{(N-1)}]^{T} where, and C(N,M) is a full rank Vandermonde matrix with terms of a geometric progression in each row. The matrix is a function of frequencies wᵢ, damping factors γᵢ, and the number of sinusoids M in the case of transients

$$C ( N , M ) = [ \begin{matrix}1 & … & 1 \\ {e}^{{jω}_{1} - {γ}_{1}} & … & {e}^{{jω}_{M} - {γ}_{M}} \\ ⋮ & ⋱ & ⋮ \\ {e}^{( {jω}_{1} - {γ}_{1} ) ( N - 1 )} & … & {e}^{( {jω}_{M} - {γ}_{M} ) ( N - 1 )}\end{matrix} ] . \qquad ( 4 )$$

The variables a, wᵢ, γᵢ and M are unknown.

Stochastic Transient Detector

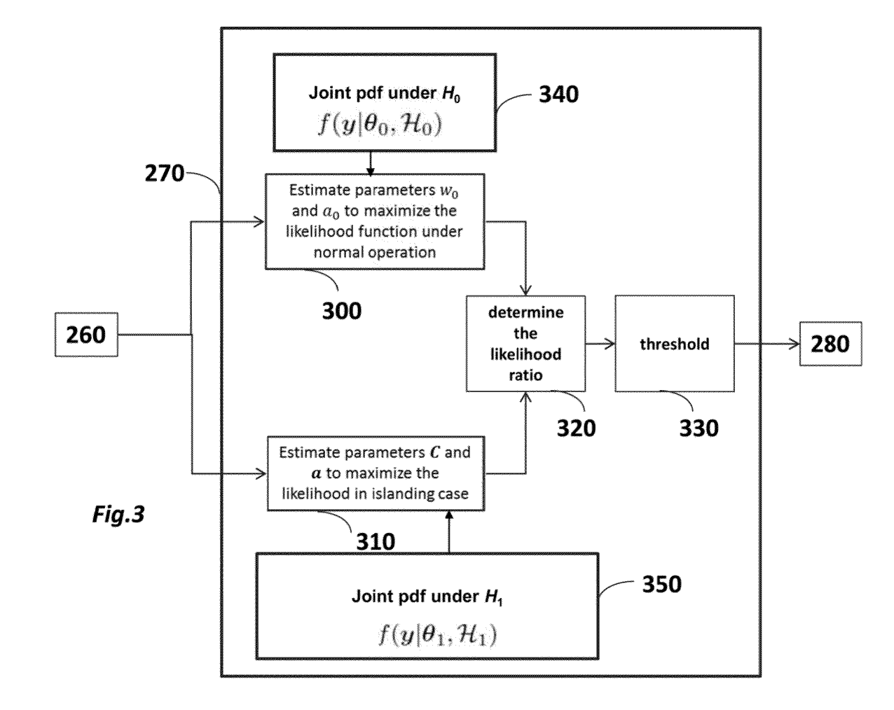

FIG. 3 shows a stochastic transient detector and process according to embodiments of the invention. The detector can be implemented in discrete electronic circuits or a general purpose processor or microprocessor. The method steps can be implemented as modules of the circuit or process. The method steps can be performed by a processor connected to memory and input/output interfaces, and the power grid.

Input to the detector are the normal/transient samples 260 measured under normal and transient conditions. A joint probability density function (pdf) 340 of the set of the voltage samples under the normal condition hypothesis H₀ contains a vector of unknowns θ₀ that includes a₀ and w₀. A joint probability density function (pdf) 350 of the set of observations under the transient condition hypothesis H₁ contains the vector of unknown θ₁ that include aᵢ and wᵢ.

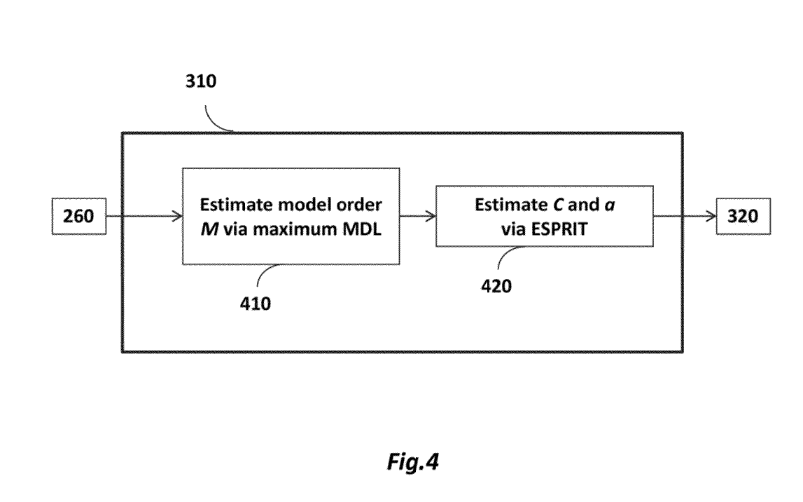

The unknown vector θ₀ is estimated 300 using a maximum likelihood estimator. The parameters C and a are estimated 310 for the case of H₁ using ESPRIT as shown in FIG. 4. The likelihood ratio

$$\frac{{max}_{{θ}_{0}} {f ( y \vert {θ}_{0} , {H}_{0} )}_{{H}_{0} }}{{max}_{{θ}_{1}} {f ( y \vert {θ}_{1} , {H}_{1} )}_{{H}_{1}}} , \qquad ( 5 )$$

of the outputs of step 300 and 310 are determined 320 and thresholded 330 to obtain the decision for the hypotheses H₀ or H₁.

As shown in FIG. 4, the model order M is estimated 410 using a maximum description length (MDL) 410, which enables us to select the hypothesis that corresponds most to the regularity in the data. The parameters C and a are estimated 420 using ESPRIT.

After all the unknown parameters a₀, w₀, C, a and M are estimated for H₀ and H₁, transient is detected 250 using a generalized likelihood ratio 320, which is compared 330 to a predetermined threshold T. The threshold can be based on a desired probability of false alarm (PFA). For a higher PFA, the threshold is smaller.

Damped Signals of Multiple Sinusoids

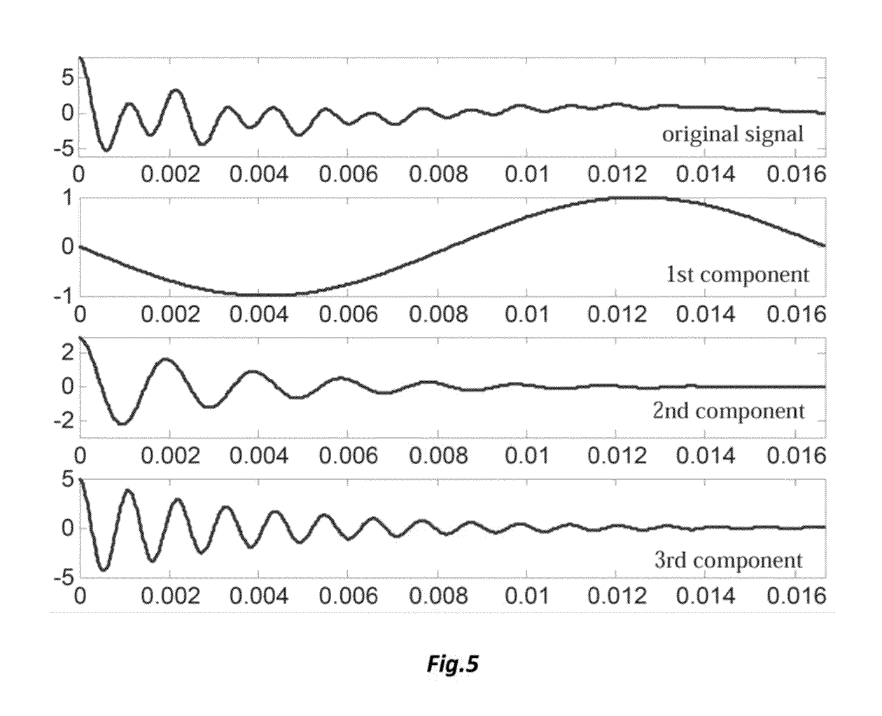

FIG. 5 shows the original signal and three components. The first component is responsible for the fundamental frequency, e.h., 60 Hz for this example. Time-wise, samples during one cycle of the fundamental frequency are used. The signal-to-noise (SNR) between the first component and the noise is ˜30 dB.

### Effect of the Invention

A power grid is a nonstationary network, and frequently internal and external circuit changes result in voltage and current transients. The transients degrade the power quality, and can cause potential damage to dedicate electrical devices, or disable critical electrical equipment.

The invention provides a method and system for detecting the transients using a binary hypothesis test. A normal condition hypothesis (H₀) for a normal condition is modeled as a single sinusoid. An alternative transient condition hypothesis (H₁) is modeled as a sum of damped sinusoids.

Because the parameters of the models are unknown, a general likelihood ratio test is used on probability distribution functions constructed from voltage sample of the grid. The likelihood ratio of the pdfs is compared to a threshold to determine if the condition of the network is normal or an abnormal transient.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A method for detecting a condition in a power grid, comprising the steps of:
modeling a normal condition hypothesis as a sinusoid, and a transient condition hypothesis as a sum of damped sinusoids;
constructing a probability density function (pdf) from voltage samples in the grid; and
comparing a likelihood ratio based on the pdf and the hypotheses to a threshold to determine the condition, wherein the steps are performed in a processor.

2. The method of claim 1, further comprising:
connecting devices to the grid power according to the condition.

3. The method of claim 1, wherein the voltage is 1-phase or 3-phase.

4. The method of claim 1, further comprising:
analyzing the samples in a stochastic detector to fit the samples to the pdf.

5. The method of claim 1, wherein the samples include normal samples and transient samples, and the normal condition hypothesis is H₀:y=a₀e, and the transient condition hypothesis is H₁:y=Ca, where y is a voltage, a is an amplitude, e is a frequency of each normal sample, and C is a full rank Vandermonde matrix of the frequencies, damping factors and sinusoids for the transient samples.

6. The method of claim 5, further comprising:
estimating a₀, a, e, and C using estimation of signal parameters via rotational invariance techniques (ESPRIT).

7. The method of claim 1, wherein the comparing further comprises:
determining a likelihood ratio of the normal pdf and the transient pdf; and
thresholding the likelihood ratio.

8. The method of claim 5, further comprising:
estimating a model order using a maximum description length to obtain the normal condition hypothesis.

9. The method of claim 7, wherein the thresholding is based on a desired probability of false alarm.
